(19) United States
(12) Patent Application Publication
(10) Pub. No.: US 2008/0246493 A1
(43) Pub. Date: Oct. 9, 2008

(54) Semiconductor Processing System With Integrated Showerhead Distance Measuring Device

(76) Inventor: DelRae H. Gardner, Tualatin, OR (US)

Correspondence Address: Christopher R. Christenson;WESTMAN, CHAMPLIN & KELLY, P.A., Suite 1400, 900 Second Avenue South, Minneapolis, MN, 55402-3319, US

(21) Appl. No.: 12/055,744

(22) Filed: Mar. 26, 2008

Related U.S. Application Data
(60) Provisional application No. 60/921,977, filed on Apr. 5, 2007.

(51) Int. Cl. G01R 27/26; C23C 16/513; H01L 21/3065

(52) U.S. Cl. 324/662; 118/712; 156/345.28; 156/345.34; 118/723 R

(57) ABSTRACT

A system for determining a distance between a showerhead of a semiconductor processing system and a substrate-supporting pedestal is provided. The system includes a showerhead having a showerhead surface from which reactive gas is expelled and a pedestal having a pedestal surface that faces the showerhead surface. A first capacitive plate is disposed on the pedestal surface. A second capacitive plate is disposed on the showerhead surface. A third capacitive plate disposed on one of the showerhead surface and the pedestal surface, but spaced from the first and second capacitive plates. Capacitance measurement circuitry is operably coupled to the first, second and third capacitive plates.

### CROSS-REFERENCE TO RELATED APPLICATION

The present application is based on and claims the benefit of U.S. provisional patent application Ser. No. 60/921,977, filed Apr. 5, 2007, the content of which is hereby incorporated by reference in its entirety.

### COPYRIGHT RESERVATION

A portion of the disclosure of this patent document contains material, which is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### BACKGROUND

Semiconductor wafer processing is a precise and exacting science with which various wafers and/or substrates are processed to become integrated circuits, LCD flat panel displays, and other such electronic devices. The current state of the art in semiconductor processing has pushed modern lithography to new limits with current commercial applications being run at the 45-nanometer scale, and Moore's Law still in effect. Accordingly, modern processing of semiconductors demands tighter and tighter process controls of the processing equipment.

Often a semiconductor processing deposition or etch processing chamber utilize a device known as a “showerhead” to introduce a reactive gas to the substrate. The device is termed a “showerhead” in that it vaguely resembles a showerhead being generally circular, and having a number of apertures through which the reactive gas is expelled onto the substrate. In the field of semiconductor manufacturing, precise and accurate measurement and adjustment of the distance between the showerhead and a substrate-supporting pedestal in such a deposition or etch processing chamber are needed in order to effectively control the process. If the distance of the gap between the showerhead and the substrate-supporting pedestal are not accurately known, the rate at which the deposition or etching occurs may vary undesirably from a nominal rate. Further, if the pedestal is inclined, to some extent, relative to the showerhead, the rate at which one portion of the substrate is processed via the deposition or etching process will be different than the rate at which other portions are processed. Accordingly, it is imperative in semiconductor processing to accurately determine both the distance of the gap, and any inclination of the substrate-supporting pedestal relative to the showerhead.

### SUMMARY

A system for determining a distance between a showerhead of a semiconductor processing system and a substrate-supporting pedestal is provided. The system includes a showerhead having a showerhead surface from which reactive gas is expelled and a pedestal having a pedestal surface that faces the showerhead surface. A first capacitive plate is disposed on the pedestal surface. A second capacitive plate is disposed on the showerhead surface. A third capacitive plate disposed on one of the showerhead surface and the pedestal surface, but spaced from the first and second capacitive plates. Capacitance measurement circuitry is operably coupled to the first, second and third capacitive plates.

### BRIEF DESCRIPTION OF THE DRAWINGS

FIG. 1 is a diagrammatic view of a semiconductor-processing chamber with which embodiments of the present invention are particularly applicable.

FIG. 2 is a diagrammatic view of a semiconductor-processing chamber in accordance with an embodiment of the present invention.

FIG. 3 is a bottom plan view of a possible showerhead configuration in accordance with an embodiment of the present invention.

FIG. 4 is a diagrammatic plan view of an alternate showerhead configuration in accordance with another embodiment of the present invention.

### DETAILED DESCRIPTION OF ILLUSTRATIVE EMBODIMENTS

Embodiments of the present invention generally employ one or more conductive regions on the showerhead and/or the substrate-supporting pedestal to form a capacitor, the capacitance of which varies with the distance between the two conductive surfaces. Preferably, surface regions on the showerhead are isolated from each other, each surface forming one plate of a capacitor, with the lower electrode or pedestal forming the other electrode. Thus, various capacitor pairs exist between the showerhead and the pedestal. The capacitance of each pair is dependent on the distance between the showerhead and pedestal at that point. A measurement is made of each capacitor plate pair, using a capacitance measuring circuit or instrument. The gap between each plate pair is determined from the measured capacitance. By this technique, the gap between the showerhead and pedestal can be determined at the various points on the showerhead corresponding with the various isolated surface regions. This allows measurement of the gap as it is adjusted, to achieve a desired gap setting at each point on the showerhead. Preferably, two or more capacitor plate pairs may be used in combination to measure gap at various points, along with a determination of overall gap, tilt and shape of the gap.

In some cases, as in the case of a plasma-enhanced chemical vapor deposition (PECVD) processing chamber, the showerhead must also function as an electrode in forming a plasma during wafer processing. The same plates on the showerhead surface that act as parts of capacitor plate pairs are, in this case, employed, together, as the plasma-forming electrode. That is, the plates are electrically isolated from one another for the capacitance measurement, but are electrically connected together when acting as the plasma-forming electrode.

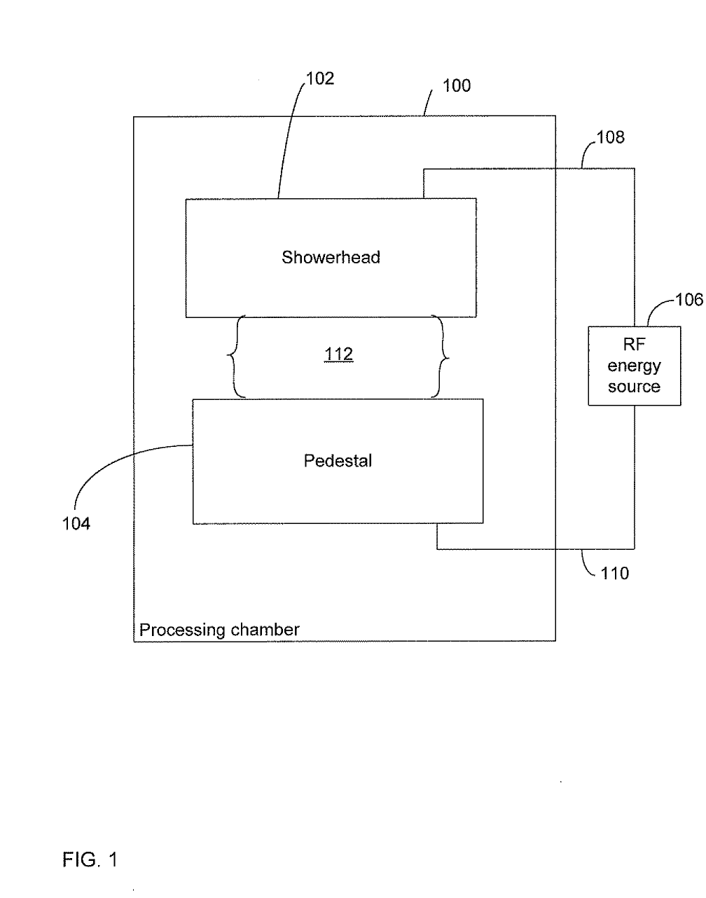

FIG. 1 is a diagrammatic view of a semiconductor-processing chamber with which embodiments of the present invention are particularly applicable. Processing chamber 100 includes a showerhead 102 disposed above, or at least spaced apart from pedestal 104. Typically, the wafer or substrate will rest upon pedestal 104 while it is processed in processing chamber 100. As illustrated in FIG. 1, a source 106 of radio frequency energy is electrically coupled to showerhead 102 and pedestal 104 via respective conductors 108 and 110. By providing radio frequency energy to showerhead 102 and pedestal 104, reactive gas introduced from showerhead 102 can form a plasma in region 112 between pedestal 104 and showerhead 102 in order to process a wafer or semiconductor substrate.

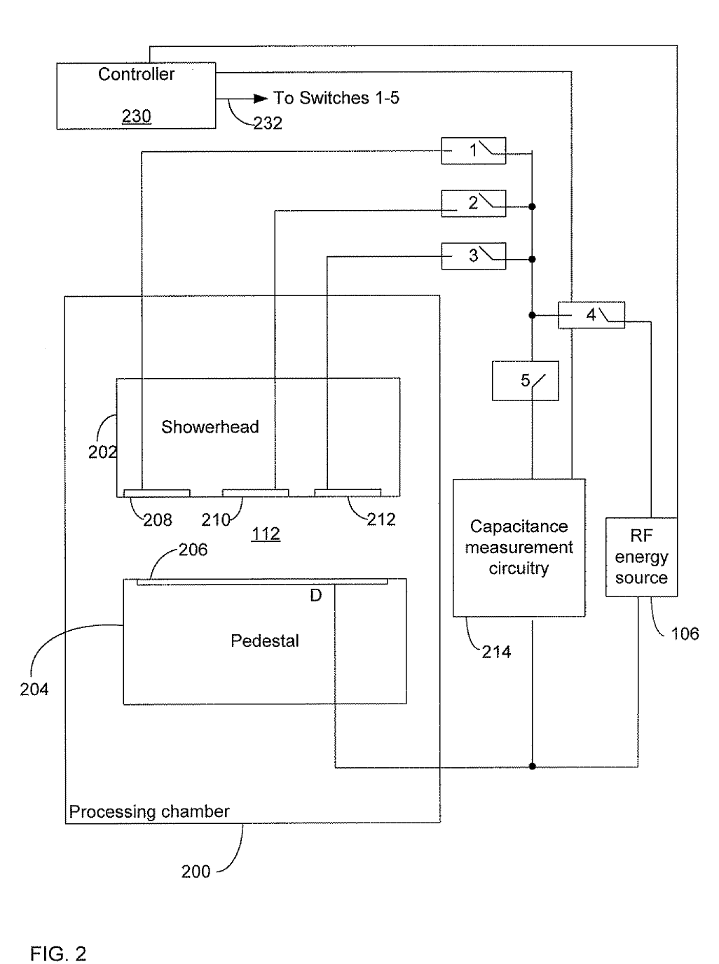

FIG. 2 is a diagrammatic view of a semiconductor-processing chamber in accordance with an embodiment of the present invention. Chamber 200 bears some similarities to chamber 100, and like components are numbered similarly. Processing chamber 200 includes pedestal 204 and showerhead 202, both of which are preferably non-conductive. Pedestal 204 includes a conductive electronic layer or plate 206 that is arranged on a surface of pedestal 204 that faces showerhead 202. Similarly, showerhead 202 preferably includes a plurality of electronic layers or conductive surfaces 208, 210 and 212. Each of electrodes 208, 210 and 212, form a respective capacitor with plate 206. The capacitance of each respective capacitor is related to the distance between each respective capacitive plate on showerhead 202, and plate 206 on pedestal 204.

As illustrated in FIG. 2, the system includes not only RF energy source 106, but also a capacitance measurement circuit 214 that can be alternately coupled to the plates 208, 210 and 212 by virtue of various switches. Circuitry for measuring varying capacitance is well known. Such circuitry may include known analog-to-digital converters as well as suitable excitation and/or driver circuitry. As illustrated in FIG. 2, each of RF energy source 106, and capacitance measurement circuit 214 is coupled to a respective switch 4, 5 such that energy source 106, and capacitance measurement circuit 214 are not coupled to capacitive plates at the same time. Thus, during normal processing, switch 5 is open and switch 4 is closed thereby coupling RF energy source 106 to the processing chamber. Further, during normal processing, all of switches 1, 2 and 3 are closed such that RF energy source 106 is coupled to all of plates 208, 210 and 212, simultaneously. During gap measurement, switch 4 is opened and switch 5 is closed. Further, only one of switches 1, 2 and 3 is closed at a time with the other switches being opened. This allows the capacitance between a particular capacitance plate such as 208, 210, 212, and plate 206 to be measured to determine the distance between showerhead 202 and the pedestal 204 at the location of the respective capacitive plate. As further illustrated in FIG. 2, a controller, such as controller 230, is preferably coupled to switches 1-5, as illustrated at reference numeral 232 and also to RF energy source 106 and capacitance measurement circuit 214. In this manner, controller 230 can suitably actuate the various switches 1-5, and engage RF energy source 106 or capacitance measurement circuit 214 when appropriate. Further, capacitance measurement circuit 214 can report the various capacitance measurements, for example by digital communication, to controller 230.

Controller 230 can also be coupled to a suitable display (not shown) such as a monitor, display panel, or series of indicator lights, to indicate the gap and/or parallelism for use by an operator. Further, controller 230 could be coupled directly to various actuators (not shown) that can generate relative movement between pedestal 204 and showerhead 202. In this way, controller 230 can dynamically adjust gap and/or parallelism without significant user interaction.

While FIG. 2 illustrates processing chamber 200 including three distinct variable capacitors, any suitable number of capacitors can be used. Further, although FIG. 2 illustrates the three variable capacitor plates 208, 210 and 212 having substantially the same size, the relative sizes can also vary.

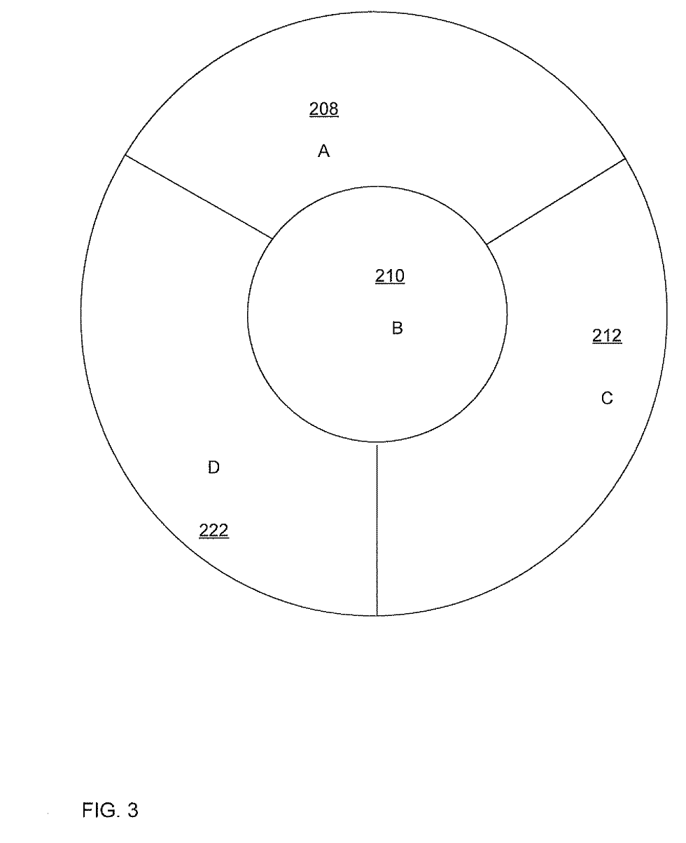

FIG. 3 is a bottom plan view of a possible showerhead configuration in accordance with an embodiment of the present invention. Each separate area 208, 210, 212 and 222 can be electrically isolated from the other areas. Each separate area includes a plate that is a plate that with plate 206 forms a capacitor whose capacitance is dependent on the gap between the showerhead 202 and pedestal 204 at that point. (Capacitance also depends on other factors, including the area of the plates, however, other factors are considered as known constants and can be compensated for in the calculation of the gap). By measuring the capacitance, the gap at each area can be determined. This enables adjustment of the gap based on the measurement of the gap. Comparison of the gaps at the various points enables adjustment of the relative gaps, which is equivalent to parallelism between showerhead 202 and pedestal 204. A comparison of the outer gaps (A, C and D) against the center gap (B) provides a way of measuring and evaluating the shape of the showerhead, whether flat, crowned or dished.

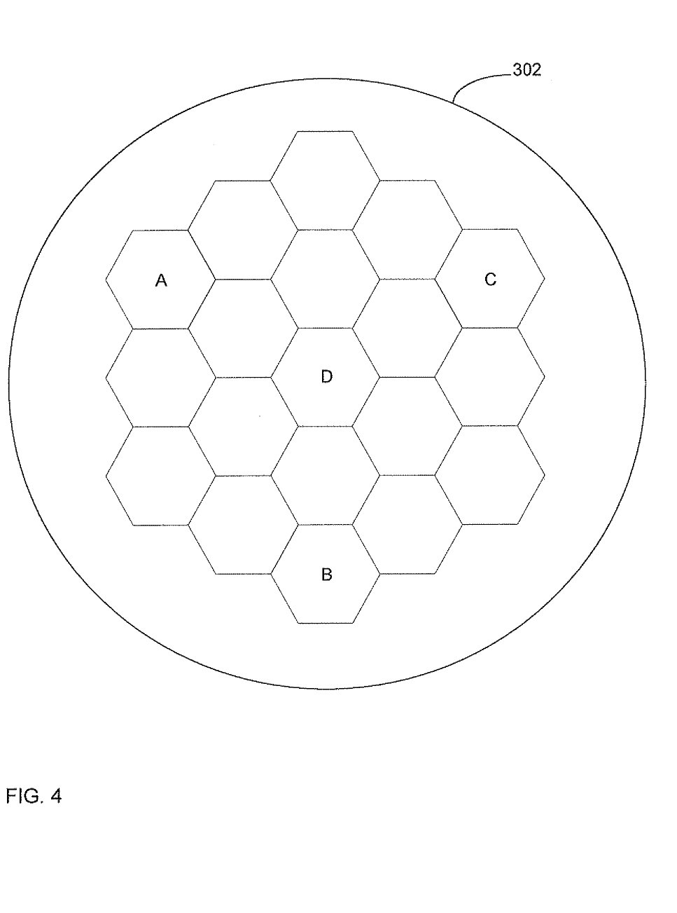

FIG. 4 shows a plan view of a showerhead 302 in accordance with another embodiment of the present invention. In this embodiment, there are several small areas, each of which can provide a gap measurement. This allows a more detailed determination of showerhead shape. In addition, one or more adjacent areas can be combined for one measurement, allowing the same type of measurements as would be provided by showerhead 202 shown in FIGS. 2 and 3.

Although the present invention has been described with reference to preferred embodiments, workers skilled in the art will recognize that changes may be made in form and detail without departing from the spirit and scope of the invention. For example, while embodiments of the present invention have generally been described with respect to various electrodes on the showerhead, the pedestal can employ, additionally, or alternatively, various electrodes.

What is claimed is:

1. A system for determining a distance between a showerhead of a semiconductor processing system and a substrate-supporting pedestal, the system comprising:
a showerhead having a showerhead surface from which reactive gas is expelled;
a pedestal having a pedestal surface that faces the showerhead surface;
a first capacitive plate disposed on the pedestal surface;
a second capacitive plate disposed on the showerhead surface;
a third capacitive plate disposed on one of the showerhead surface and the pedestal surface, but spaced from the first and second capacitive plates; and
capacitance measurement circuitry operably coupled to the first, second and third capacitive plates.

2. The system of claim 1, wherein the third capacitive plate is disposed on the showerhead surface.

3. The system of claim 1, wherein the showerhead is circular, and wherein at least one of the second and third plates is also circular.

4. The system of claim 1, wherein the capacitive measurement circuitry provides an indication of capacitance between the first and second plates and between the first and third plates.

5. The system of claim 1, and further comprising:
a controller;
a source of RF energy;
a first switch coupling the source of RF energy to one of the substrate-supporting pedestal and the showerhead;
a second switch coupling the capacitance measurement circuitry to one of the substrate supporting pedestal and the showerhead; and
wherein the controller is coupled to the source of RF energy, the capacitance measurement circuitry and the first and second switches to engage the RF energy source and close the first switch during a normal operating mode, and to engage the capacitance measurement circuitry and close the second switch during a measurement mode.

6. The system of claim 5, wherein the first and second switches are operated opposite of each other, such that when the first switch is closed, the second switch is open, and when the second switch is closed, the first switch is open.

7. The system of claim 5 and further comprising a third switch operably coupling the second capacitive plate to the first and second switches.

8. The system of claim 7 and further comprising a fourth switch operably coupling the third capacitance plate to the first and second switches.

9. A method of measuring electrode separation in a semiconductor processing chamber having a first and second surfaces between which a semiconductor is processed, the method comprising:
providing first and second capacitive plates on one of the first and second surfaces, which first and second capacitive plates are spaced and isolated from one another;
providing a third capacitive plate on the other of the first and second surfaces; and
measuring the capacitance between the first and third capacitive plate and measuring the capacitances between the second and third capacitive plate, and providing an indication of separation based upon the measured capacitances.

10. The method of claim 9, wherein the indication of separation is an overall indication of separation between the first and second surfaces.

11. The method of claim 10, wherein the indication of separation is used to adjust the separation.

12. The method of claim 9, wherein the indication of separation is used to provide an indication of parallelism.

13. The method of claim 12 and further comprising adjusting parallelism of the surfaces relative to one another based upon the parallelism indication.

14. The method of claim 9, wherein the indication of the separation is used to provide a measure of electrode shape.

15. A showerhead for use in a semiconductor processing system, the showerhead comprising:
a plurality of conductive regions, in which each region is electrically isolated from other regions.

16. The showerhead of claim 15, wherein the plurality of conductive regions are substantially co-planar.

17. The showerhead of claim 15 and further comprising a capacitance measurement circuit operably coupled to each conductive region.
